(19) United States
(12) Patent Application Publication
(10) Pub. No.: US 2025/0034712 A1
(43) Pub. Date: Jan. 30, 2025

(54) METHODS AND APPARATUS IN-SITU MEASUREMENTS

(71) Applicant: ASM IP Holding B.V., Almere (NL)

(72) Inventors: Anirudhan Chandrasekaran, Scottsdale, AZ (US); Jereld Lee Winkler, Gilbert, AZ (US); Shubham Garg, Gilbert, AZ (US); Ryan Paull, Gilbert, AZ (US)

(21) Appl. No.: 18/782,321

(22) Filed: Jul. 24, 2024

Related U.S. Application Data
(60) Provisional application No. 63/529,580, filed on Jul. 28, 2023.

(51) Int. Cl. C23C 16/458; G01B 5/06

(52) U.S. Cl. CPC C23C 16/4585; G01B 5/066

(57) ABSTRACT

Various embodiments of the present technology may provide in-situ metrology. A system may include a first sensor embedded within a susceptor and flush with a top surface of the susceptor. The system may also include lift pin pads having a second sensor arranged to contact a lift pin. The system may also include a third sensor arranged outside of a reaction chamber and adjacent to a view port. The system may also include a processor to receive output signals from one or more of the sensors and use the output signals to determine a film thickness on a wafer.

### CROSS-REFERENCE TO RELATED APPLICATIONS

This application is a nonprovisional of, and claims priority to and the benefit of, U.S. Provisional Patent Application No. 63/529,580, filed Jul. 28, 2023 and entitled “METHODS AND APPARATUS IN-SITU MEASUREMENTS,” which is hereby incorporated by reference herein.

### FIELD OF INVENTION

The present disclosure generally relates to a method and apparatus for in-situ measurements. More particularly, the present disclosure relates to measuring an amount of deposited material during semiconductor manufacturing.

### BACKGROUND OF THE TECHNOLOGY

Metrology may be used to analyze and evaluate whether a process is occurring as it should be during film deposition. One metric that may be important to measure is the thickness of the film that has been deposited on a wafer. This thickness can inform whether the correct amount of deposition has occurred. Conventional methods to measure the film thickness are done ex-situ (outside of the reaction chamber), which are not real-time measurements and are not as accurate since changes to film may occur after removal from the chamber and exposure to a different environment. Moreover, making these measurements in a different location can negatively impact throughput. During processing, the film can also accumulate on components of the reaction chamber, which can change the thermal characteristics of the components and may lead to non-uniform heating and thus wafer non-uniformity.

### SUMMARY OF THE INVENTION

Various embodiments of the present technology may provide in-situ metrology. A system may include a first sensor embedded within a susceptor and flush with a top surface of the susceptor. The system may also include lift pin pads having a second sensor arranged to contact a lift pin. The system may also include a third sensor arranged outside of a reaction chamber and adjacent to a view port. The system may also include a processor to receive output signals from one or more of the sensors and use the output signals to determine a film thickness on a wafer.

According to one aspect, an apparatus comprises: a susceptor configured to support a substrate, and comprising a first surface and a second, opposing surface, and a plurality of first through-holes extending from the first surface to the second surface and a plurality of second through-holes extending from the first surface to the second surface; a set of first pins, each first pin arranged within a through-hole from the plurality of first through-holes, wherein each first pin is configured to have multiple positions; and a set of second pins, each second pin comprising: a first end adjacent to the first surface of the susceptor and a second end, opposite the first end, wherein: each second pin is arranged within a through-hole from the plurality of second through-holes; and each second pin has a single, fixed position; and a sensor disposed at and electrically connected to the first end.

In one embodiment, the sensor comprises a quartz crystal microbalance and the set of second pins comprises an electrically-conductive material.

In one embodiment, the sensor is flush with the first surface.

In one embodiment, the susceptor further comprises a plurality of third through-holes coupled to a vacuum source.

In one embodiment, the set of second pins are arranged in a circular pattern.

In one embodiment, each sensor generates an output signal corresponding to a change in frequency of the sensor.

In one embodiment, the apparatus further comprises a processor configured to receive each output signal and determine a mass value based on the change in frequency.

In one embodiment, the apparatus further comprises a processor configured to receive each output signal and determine a thickness map of a film on the substrate based on a combination of the output signals and a location of each sensor relative to the other sensors.

In one embodiment, the apparatus further comprises a mechanism attached to each pin from the set of second pins and configured to apply a force on the sensor.

In yet another aspect, an apparatus comprises: a susceptor comprising a first surface and an opposing, second surface; a plurality of through-holes extending from the first surface to the second surface; a plurality of lift pins, each lift pin disposed within a respective through-hole from the plurality of through-holes; and a plurality of sensors embedded within the susceptor, and each sensor comprising a sensing surface disposed flush with the first surface, wherein the sensor is configured to generate an output signal corresponding to a change in frequency of the sensing surface.

In one embodiment, the sensor comprises a quartz crystal microbalance.

In one embodiment, the susceptor further comprises a plurality of third through-holes coupled to a vacuum source.

In one embodiment, the plurality of sensors are arranged in a circular pattern.

In one embodiment, each sensor generates an output signal corresponding to a change in frequency of the sensor.

In one embodiment, the apparatus further comprises a processor configured to receive each output signal and determine a mass value based on the change in frequency.

In one embodiment, the apparatus further comprises a processor configured to receive each output signal and determine a thickness map of a film on the substrate based on a combination of the output signals and a location of each sensor relative to the other sensors.

In yet another aspect, a system comprises: a reaction chamber; a susceptor disposed within the reaction chamber and comprising a first surface and an opposing, second surface; a plurality of sensors embedded within the susceptor, and each sensor comprising a sensing surface disposed flush with the first surface, wherein the sensor is configured to generate an output signal corresponding to a change in frequency of the sensing surface; and a processor electrically connected to each sensor and configured to receive each output signal and determine a thickness map based on a combination of the output signals and a location of each sensor relative to the other sensors.

In one embodiment, the system further comprises a mechanism attached to each pin from the set of second pins and configured to apply a force on the sensor.

In one embodiment, wherein the sensors are arranged in a circular pattern.

In one embodiment, the processor is further configured to detect when the change in frequency is outside a predetermined range and generate an error signal in response.

In yet another aspect, a system comprises: a susceptor disposed within an interior space of a reaction chamber, wherein the susceptor comprises a plurality of through-holes; a plurality of pins disposed within a respective through-hole from the plurality of through-holes; a plurality of pin pads disposed below the susceptor, wherein each pin pad is aligned with one pin from the plurality of pins; a sensor disposed on a top surface of the pin pad, wherein the sensor generates a signal corresponding to mass; and a processor coupled to the sensor and configured to receive the signal, determine a change in mass based on the signal, and determine a film thickness based on the determined change in mass.

In yet another aspect, a system comprises: a reaction chamber comprising a sidewall and a bottom surface that is perpendicular to the sidewall, wherein the sidewall and bottom surface define an interior space of the reaction chamber; a susceptor disposed within the interior space; a view port disposed within the sidewall; an emissometer disposed on an exterior of the reaction chamber and adjacent to the view port, wherein the first emissometer generates an output signal; and a processor connected to the emissometer and configured to receive the output signal and detect a change in value of the output signal.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 is a block diagram of a system in accordance with various embodiments of the present technology;

FIG. 2 representatively illustrates a cross-sectional view of a susceptor in accordance with various embodiments of the present technology; and

FIG. 3 representatively illustrates a top view of a susceptor in accordance with various embodiments of the present technology.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various reaction chambers, susceptors, lift pins, processors, and showerhead plates.

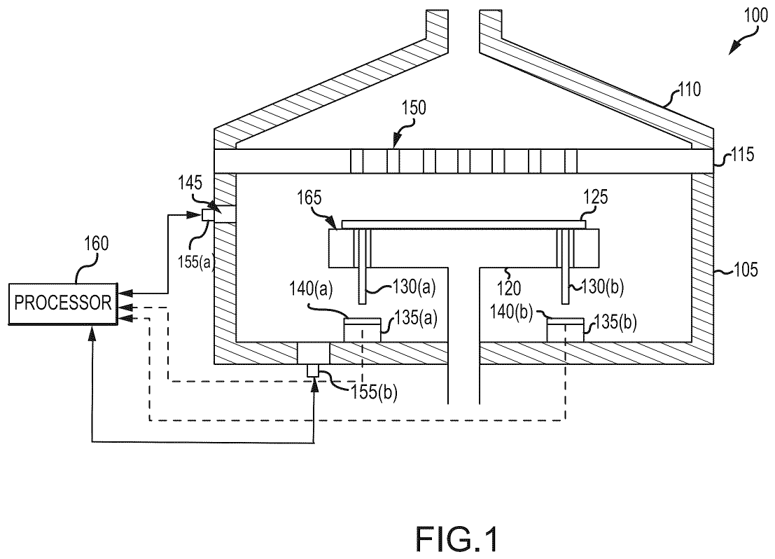

Referring to FIG. 1, an exemplary system 100 may comprise a reactor comprising a showerhead assembly and a reaction chamber 105. The reactor may be used to deposit a film on a substrate, such as a wafer 125. The reaction chamber 105 may comprise a plurality of sidewalls and a bottom surface that form an interior space.

In an exemplary embodiment, the reaction chamber 105 may further comprise a first view port 145 disposed within a sidewall. The first view port 145 may extend through the entire thickness of the sidewall such that the interior space is visible from outside the reaction chamber 105 through the first view port 145. The first view port 145 may be formed from quartz, sapphire, or any other suitable transparent material. The first view port 145 may be positioned in an upper region of the sidewall and away from the bottom surface.

In various embodiments, the reaction chamber 105 may further comprise a second view port 170 disposed within the bottom surface of the reaction chamber 105. The second view port 170 may extend through the entire thickness of the bottom surface such that the interior space is visible from outside the reaction chamber 105 through the second view port 170. The second view port 170 may be formed from quartz, sapphire, or any other suitable transparent material. The second view port 170 may be positioned in a location that provides a direct line of sight to a bottom surface of a susceptor 120 and the edge of the susceptor 120.

In various embodiments, the showerhead assembly may comprise a lid 110 and a showerhead plate 115. The showerhead plate 115 may comprise a plurality of through holes 150 configured to flow a gas into the interior space of the reaction chamber 105. The showerhead assembly may be arranged above the reaction chamber 105 and enclose the interior space of the reaction chamber 105. In particular, the showerhead plate 115 may rest directly on the sidewalls of the reaction chamber 105.

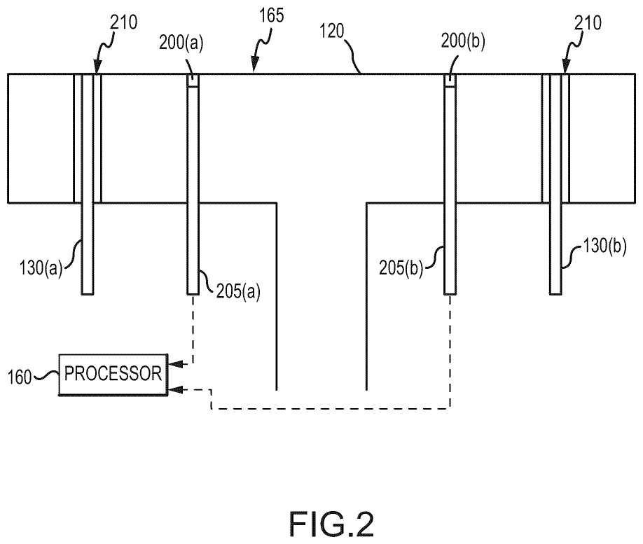

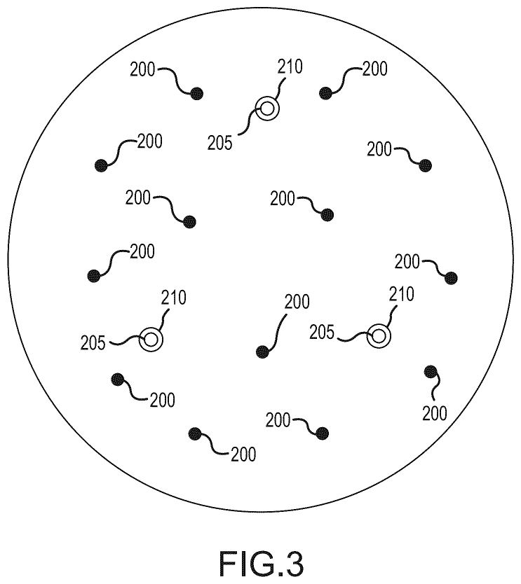

In various embodiments, and referring to FIGS. 1-3, the susceptor 120 may be configured to support the wafer 125 during processing/film deposition and may be disposed within the interior space of the reaction chamber 105. The susceptor 120 may be formed from a ceramic material, such as aluminum oxide, or a metal material, such as a metal alloy C22 or any other suitable metal or metal alloy. The susceptor 120 may comprise first, upward-facing surface 165, and a second, opposing downward-facing surface. In various embodiments, and during processing, the wafer 125 is positioned on the first surface 165. In various embodiments, the susceptor 120 may comprise a heating element (not shown) embedded within the susceptor 120. The heating elements may be utilized to control a temperature of the susceptor 120.

In various embodiments, the susceptor 120 may comprise a plurality of first through-holes 210 extending from the first surface 165 to the second surface. In an exemplary embodiment, the susceptor 120 comprises three through-holes 210, arranged in a triangular pattern.

In some embodiments, the susceptor 120 may be configured to move up to a processing position (as illustrated in FIG. 1) and down to a wafer unloading position. Alternatively, the susceptor 120 may be in a fixed position.

In some embodiments, the susceptor 120 may further comprise a plurality of second through-holes.

In various embodiments, the system 100 may further comprise a plurality of lift pins 130. Each lift pin 130 may be disposed within a respective through hole 210 in the susceptor 120 and extend below the downward-facing surface of the susceptor 120. The lift pins 130 may be formed from a ceramic material or a metal material.

In various embodiments, the system 100 may further comprise a plurality of lift pin pads 135. The lift pin pads 135 may be disposed below the susceptor 120. For example, the lift pin pads 135 may be affixed to the bottom surface of the reaction chamber 105. Alternatively, the lift pin pads 135 may be movable relative to the susceptor 120. For example, the lift pin pads 135 may be coupled to an actuator or the like to move the lift pin pads 135 up and down.

Each lift pin pad 135 is arranged directly below and aligned with a respective lift pin 130. For example, a first lift pin pad 135(a) is arranged directly below a first lift pin 130(a) and a second lift pin pad 135(b) is arranged directly below the second lift pin 130(b). Each lift pin pad 135 may have a top surface with an area large enough to support the respective lift pin 130.

In various embodiments, each lift pin pad 135 may comprise a first sensor 140 on the top surface of the pin pad 135. In an exemplary embodiment, the first sensor 140 may comprise a quart crystal microbalance configured to generate a first sensor output signal. In an exemplary embodiment, each pin pad 135 from the plurality of pin pads 135 comprises a dedicated and independent first sensor 140.

In various embodiments, the system 100 may further comprise a thermal sensor 155 configured to measure thermal radiation. The thermal sensor 155 may be disposed outside of the reaction chamber 105 and adjacent to the view port 145, 170. For example, a first thermal sensor 155(a) may be adjacent to the first view port 145 and a second thermal sensor 155(b) may be adjacent to the second view port 170. The first thermal sensor 155(a) may be positioned to measure the thermal radiation of components inside the reaction chamber 105, such as the first surface 165 of the susceptor 120, the showerhead plate 115, and the opposite sidewall of the reaction chamber 105. Similarly, the second thermal sensor 155(b) may be positioned to measure the thermal radiation of components inside the reaction chamber 105, in particular, the bottom surface of the susceptor 120 and the edge of the susceptor 120. The first and second thermal sensors 155(a), 155(b) may be fixedly attached to the outside the reaction chamber 120 or rotatably attached. The thermal sensor 155 may comprise an emissometer or a pyrometer, or any other sensor suitable for measuring thermal radiation or thermal emissivity. The thermal sensor 155 may generate a thermal sensor output signal.

In some embodiments, the system 100 may further comprise a set of second sensors 200. Each second sensor 200 may generate a second sensor output signal. The second sensor output signal may indicate a change in frequency of the respective sensor 200. The set of second sensors 200 may be disposed at the first surface 165 of the susceptor 120. In particular, the set of second sensors 200 may be flush with the first surface 165. The set of second sensors 200 may be arranged in a uniform pattern (e.g., circular and/or equidistant spacing between sensors) across the susceptor 120 or any other suitable pattern. Each second sensor output signal may also correspond to a particular location within the susceptor 120. In an exemplary embodiment, each sensor from the set of second sensors 200 comprises a quartz crystal microbalance.

In various embodiments, the system 100 may further comprise a processor 160 configured to receive sensor signals and generate various control signals based on the received sensor signals. For example, the processor 160 may receive output signals from the first sensors 140, the second sensors 200, and the thermal sensors 155. The processor 160 may be configured to generate a thickness map of a film on the wafer 125 based on signals from the first sensors 140 and/or the second sensors 200. For example, the processor 120 may be configured to translate the output signal from the first sensor 140 or the second sensor 200 to a mass value. In some cases, the processor 120 may utilize a lookup table of predetermined values or compute the mass using an algorithm.

In addition, the processor 160 may receive output signals from the thermal sensors 155. The processor 160 may utilize these outputs signals to determine a change in emissivity over time. The processor 160 may then use the change in emissivity to generate an alert or other message to inform the system 100 (or an operator) that maintenance or a cleaning process needs to be performed on the reaction chamber 105 and/or the susceptor 120.

In various embodiments, the processor 160 may be configured to transmit a control signal to various components of the system 100, such as the susceptor 120 and heating element within the susceptor 120. For example, the processor 160 may control the movement of the susceptor 120 and may also control the temperature of the susceptor 120 by operating the heating element.

The system 100 may further comprise a set of electrical interconnects 205 configured to provide an electrical connection. For example, each electrical interconnect 205 may electrically couple the second sensor 200 to the processor 160, and be configured to transmit the second sensor output signal to the processor 160. Each electrical interconnect 205 may be formed from a material that is electrically conductive, such as a metal material.

In some embodiments, the electrical interconnect 205 may comprise a pin having a rigid form. In the present case, each pin may be disposed within a through-hole from the plurality of second through-holes in the susceptor 120. A first end of the pin may be coupled to a sensor from the set of second sensors 200 to provide an independent electrical connection to the sensor 200.

In some embodiments, the electrical interconnect 205 may comprise a flexible wire embedded within the susceptor 120.

Each electrical interconnect 205 may be in a fixed position within the through-hole. Alternatively, each electrical interconnect 205 may be movable within the through-hole. For example, in a case where the electrical interconnect is a pin, a second end of the pin 205 may be coupled to a mechanism, such as an actuator (not shown), that applies a force to move the pin 205 and the respective sensor 200 up and down.

In various operations, the system 100 may generate a thickness map of a film on the wafer 125. In particular, the processor 160 may move the susceptor 120 to the processing position. During processing, the second sensors 200 may generate output signals indicating a change in frequency of each of the second sensors 200 and transmit the output signals to the processor 160. The processor 160 may then translate the change in frequency to a mass value for each second sensor 200. Since the location of each second sensor 200 is known, the processor 160 may then generate a thickness map of the film on the wafer 125 based on the mass value. The thickness map may indicate whether the film being deposited on the wafer 125 is uniform. If the thickness of the film is not uniform, the system 100 may generate an alert to stop processing or implement a processing scheme to correct the non-uniformity, such as tuning the temperature in a particular area of the susceptor, tuning the pressure in the reaction chamber 105, or the like.

Additionally or alternatively, the processor 160 may move the susceptor 120 down to the wafer unloading position. When the susceptor 120 moves down, the lift pins 130 make contact with the lift pin pads 135 and the lift pins lift the wafer 125 off the surface of the susceptor 120. In this position, the first sensors 140 may generate output signals indicating a change in frequency of each of the first sensors 140 and transmit the output signals to the processor 160. The processor 160 may then translate the change in frequency to a mass value for each first sensor 140. Since the location of each first sensor 140 is known, the processor 160 may then generate a thickness map of the film on the wafer 125 based on the mass value. The thickness map may indicate whether the film being deposited on the wafer 125 is uniform. If the thickness of the film is not uniform, the system 100 may generate an alert to stop processing or implement a processing scheme to correct the non-uniformity, such as tuning the temperature in a particular area of the susceptor, tuning the pressure in the reaction chamber 105, or the like.

In addition, the system 100 may determine when maintenance and/or cleaning of the reaction chamber 105 and other components, such as the susceptor 120 and showerhead plate 115, may be desired. In particular, one or more of the thermal sensors 155 may generate an output signal indicating the thermal radiation of the surface of the component and transmit the output signal to the processor 160. The processor 160 may then utilize the thermal radiation data to determine whether maintenance or cleaning is needed. As film deposits and accumulates on the surfaces of the components, the thermal radiation of the components will change. For example, as film accumulates on the susceptor 120 or showerhead plate 115, the thermal radiation will decrease. This may indicate that the susceptor 120 is not heating the wafer 125 to a desired temperature, which may lead to non-uniform film deposition. As such, if the thermal radiation value drops below a predetermined threshold value, the processor 160 may generate an alert or other indicator that a chamber clean or maintenance is needed.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

What is claimed is:

1. An apparatus, comprising:
a susceptor configured to support a substrate, and comprising a first surface and a second, opposing surface, and a plurality of first through-holes extending from the first surface to the second surface and a plurality of second through-holes extending from the first surface to the second surface;
a set of first pins, each first pin arranged within a through-hole from the plurality of first through-holes, wherein each first pin is configured to have multiple positions; and
a set of second pins, each second pin comprising:
a first end adjacent to the first surface of the susceptor and a second end, opposite the first end, wherein:
each second pin is arranged within a through-hole from the plurality of second through-holes; and
each second pin has a single, fixed position; and
a sensor disposed at and electrically connected to the first end.

2. The apparatus according to claim 1, wherein the sensor comprises a quartz crystal microbalance and the set of second pins comprises an electrically-conductive material.

3. The apparatus according to claim 1, wherein the sensor is flush with the first surface.

4. The apparatus according to claim 1, wherein the susceptor further comprises a plurality of third through-holes coupled to a vacuum source.

5. The apparatus according to claim 1, wherein the set of second pins are arranged in a circular pattern.

6. The apparatus according to claim 1, wherein each sensor generates an output signal corresponding to a change in frequency of the sensor.

7. The apparatus according to claim 6, further comprising a processor configured to receive each output signal and determine a mass value based on the change in frequency.

8. The apparatus according to claim 6, further comprising a processor configured to receive each output signal and determine a thickness map of a film on the substrate based on a combination of the output signals and a location of each sensor relative to the other sensors.

9. The apparatus according to claim 1, further comprising a mechanism attached to each pin from the set of second pins and configured to apply a force on the sensor.

10. An apparatus, comprising:
a susceptor comprising
a first surface and an opposing, second surface;
a plurality of through-holes extending from the first surface to the second surface;
a plurality of lift pins, each lift pin disposed within a respective through-hole from the plurality of through-holes; and
a plurality of sensors embedded within the susceptor, and each sensor comprising a sensing surface disposed flush with the first surface, wherein the sensor is configured to generate an output signal corresponding to a change in frequency of the sensing surface.

11. The apparatus according to claim 10, wherein the sensor comprises a quartz crystal microbalance.

12. The apparatus according to claim 10, wherein the susceptor further comprises a plurality of third through-holes coupled to a vacuum source.

13. The apparatus according to claim 10, wherein the plurality of sensors are arranged in a circular pattern.

14. The apparatus according to claim 10, wherein each sensor generates an output signal corresponding to a change in frequency of the sensor.

15. The apparatus according to claim 14, further comprising a processor configured to receive each output signal and determine a mass value based on the change in frequency.

16. The apparatus according to claim 14, further comprising a processor configured to receive each output signal and determine a thickness map of a film on the substrate based on a combination of the output signals and a location of each sensor relative to the other sensors.

17. A system, comprising:
a reaction chamber;
a susceptor disposed within the reaction chamber and comprising a first surface and an opposing, second surface;
a plurality of sensors embedded within the susceptor, and each sensor comprising a sensing surface disposed flush with the first surface, wherein the sensor is configured to generate an output signal corresponding to a change in frequency of the sensing surface; and
a processor electrically connected to each sensor and configured to receive each output signal and determine a thickness map based on a combination of the output signals and a location of each sensor relative to the other sensors.

18. The system according to claim 17, further comprising a mechanism attached to each pin from the set of second pins and configured to apply a force on the sensor.

19. The system according to claim 17, wherein the sensors are arranged in a circular pattern.

20. The system according to claim 17, wherein the processor is further configured to detect when the change in frequency is outside a predetermined range and generate an error signal in response.

21. A system, comprising:
a susceptor disposed within an interior space of a reaction chamber, wherein the susceptor comprises a plurality of through-holes;
a plurality of pins disposed within a respective through-hole from the plurality of through-holes;
a plurality of pin pads disposed below the susceptor, wherein each pin pad is aligned with one pin from the plurality of pins;
a sensor disposed on a top surface of the pin pad, wherein the sensor generates a signal corresponding to mass; and
a processor coupled to the sensor and configured to receive the signal, determine a change in mass based on the signal, and determine a film thickness based on the determined change in mass.

22. A system, comprising:
a reaction chamber comprising a sidewall and a bottom surface that is perpendicular to the sidewall, wherein the sidewall and bottom surface define an interior space of the reaction chamber;
a susceptor disposed within the interior space;
a view port disposed within the sidewall;
an emissometer disposed on an exterior of the reactor and adjacent to the view port, wherein the first emissometer generates an output signal; and
a processor connected to the emissometer and configured to receive the output signal and detect a change in value of the output signal.
